(19) United States
(12) Patent Application Publication
(10) Pub. No.: US 2005/0078457 A1
(43) Pub. Date: Apr. 14, 2005

(54) Small memory card

(76) Inventors: Jackson Hsieh, Hsinchu Hsien (TW); Jichen Wu, Hsinchu Hsien (TW); Abnet Chen, Hsinchu Hsien (TW)

Correspondence Address: PRO-TECHTOR INTERNATIONAL, 20775 Norada Court, Saratoga, CA, 95070-3018, US

(21) Appl. No.: 10/683,839

(22) Filed: Oct. 9, 2003

(51) Int. Cl. H05K 7/20

(52) U.S. Cl. 361/719

(57) ABSTRACT

A small memory card includes a first substrate, a heat sink, a second substrate, at least one upper memory chip, at least one bottom memory chip and a glue layer. The heat sink is arranged between the first substrate and second substrate, and contacted with the metal, which are filled within the plurality of through holes, which formed between the first substrate and second substrate. And each of the upper memory chips and bottom memory chips are mounted on the first substrate and the second substrate, so that the heat of the upper and bottom memory chips may be traveled to the heat sink via the metal, which is filled within the through hole, then the heat will be dispersed. Thus, the small memory card of present invention having high function of disperses heat to promote its durability and lifetime effectively, the manufacturing processes must be simplified and the manufacturing cost must decrease also.

### BACKGROUND OF THE INVENTION

1. Field of the Invention

The present invention relates to a small memory card, and in particular to a small memory card that has a long lifetime and high durability.

2. Description of the Related Art

The prior method for producing a general memory card always packs chips to single integrated circuit, then mounts the IC onto a printed circuit board by the way of surface mount technique (SMT). The chip may be a memory element, such as flash memory. The golden fingers mounted on the printed circuit board for inserting into a slot of a computer main-board. In addition to some passive elements such as resistance, capacitor and inductor are mounted on the memory card.

Referring to FIG. 1 showing a side schematic illustrate of a prior memory card, the golden finger 15 is used to insert into a slot of a computer main-board, there are active elements and passive elements on the module card, the active elements usually are packed to an integrated circuit 11. Each integrated circuit 11 encapsulates a chip 12, the chip 12 may be a memory chip, for example a flash memory chip. The pins 13 of integrated circuit 11 are mounted on the printed circuit board 14 of the memory card by SMT, the printed circuit board 14 has a solder point 17 connected to pin 13. The prior arts has the following disadvantages:
1. A chip 12 must be packed then mounted on the circuit board 14, so more steps is unnecessary leads to the cost in manufacturing and packing will be increased.
2. A memory card always includes many ICs so that the integrated circuit 11 must be mounted on the PCB 14 one by one during manufacturing the module card.
3. The cost of SMT is expensive. Special manufacture devices such as a SMT machine and a solder furnace will extra the cost of equipment.
4. The memory card is manufactured separately so that the throughput is low.
5. As a result of integrated circuit 11 cannot be dispersed heat effectively, therefore the quality and durability of the small memory card is not excellent.

### SUMMARY OF THE INVENTION

The object of the present invention is to provide a small memory card may be manufactured conveniently, the manufacturing processes may be simplified and the manufacturing cost may decreased.

Another object of the present invention is to provide a small memory card having high function of disperse heat to promote its durability and lifetime effectively.

To achieve the above-mentioned object, the present invention includes a first substrate, a heat sink, and a second substrate, at least one upper memory chip, at least one bottom memory chip, and a glue layer. The first substrate has an upper surface and a lower surface, a plurality of the connected points, a plurality of golden fingers are formed on the upper surface of the substrate connected electrically the plurality of connected points and a plurality of the through hole penetrate upper surface to lower surface, and the through hole be filled with metals, the heat sink has a top surface and a bottom surface, the top surface is formed on the lower surface of the first substrate contact with the metals which are filled within the plurality of through holes of the substrate, the second substrate has an upper surface and a lower surface, the lower surface formed a plurality of connected points and a plurality of through holes penetrate upper surface to lower surface, and the through holes filled with metals, the upper surface of the second substrate is mounted on the bottom surface of the heat sink, and the metals which are filled within the plurality of through holes contact with the heat sink, the upper memory chip is arranged on the upper surface of the first substrate and connected electrically to connected points of the first substrate by way of coating manner, the bottom memory chip is arranged on the lower surface of the second surface and connected electrically to connected points of the second substrate, and the glue layer coated the upper surface of the first substrate and the lower surface of the second substrate for encapsulating each of the up memory chips and bottom memory chips at the same time.

According to one aspect of the present invention, the heat of the upper memory chip and bottom memory chip may be traveled to the heat sink via the metal, which are filled within the plurality of through holes. Therefore, proving the durability and dependability of the small memory card.

### BRIEF DESCRIPTION OF THE DRAWINGS

FIG. 1 is a schematic illustrate showing a conventional small memory card structure.

FIG. 2 is the first schematic illustrates showing a small memory card structure of the present invention.

FIG. 3 is the second schematic illustrates showing a small memory card structure of the present invention.

FIG. 4 is the third schematic illustrates showing a small memory card structure of the present invention.

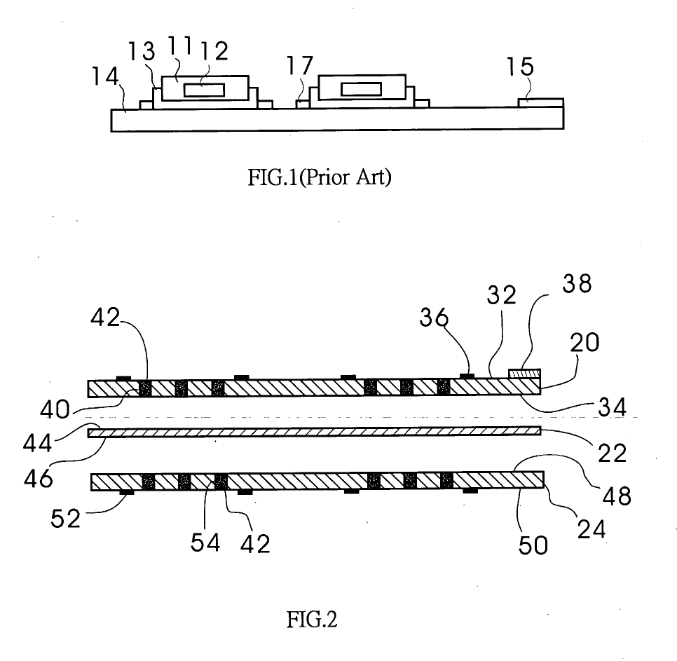

### DETAILED DESCRIPTION OF THE INVENTION

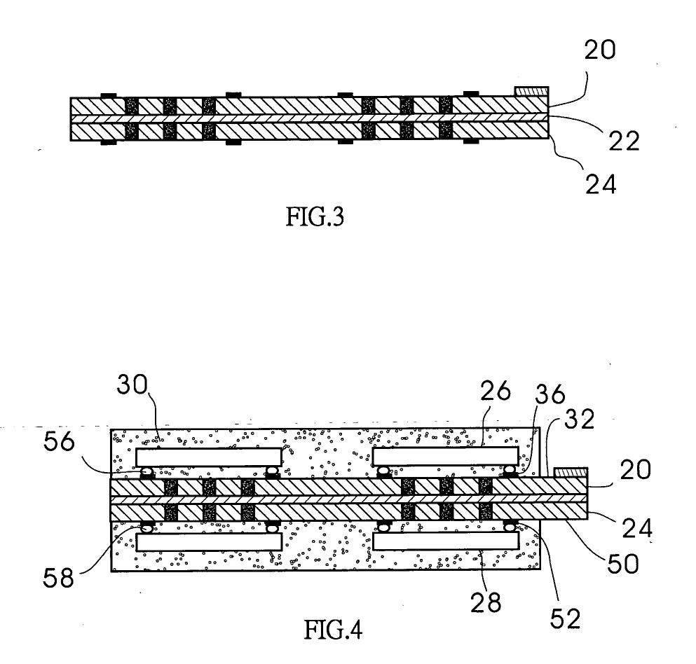

FIG. 2, FIG. 3, and FIG. 4 are the schematic illustrates showing a small memory card structure of the present invention, which include a first substrate 20, a heat sink 22, a second substrate 24, at least one upper memory chip 26, at least one bottom memory chip 28 and a glue layer 30.

The first substrate 20 has an upper surface 32 and a lower surface 34, the upper surface 32 formed with a plurality of contact points, 36 and a plurality of golden fingers 38 are electrically connected to a plurality of connected points 36, and a plurality of through holes 40 penetrate upper surface 32 to lower surface 34, the through holes 40 are filled metals 42, the metal 42 may be copper, the first substrate 20 is used to arrange in an electric device for electrically connecting the golden finger 38 to this electric device.

The heat sink 22 is made of copper or aluminum, formed a top surface 44 and a bottom surface 46, the top surface 44 is mounted on the lower surface 34 of the first substrate 20 and contacted with the metal 42 which is filled within a plurality of through holes 40 of the first substrate 20.

The second substrate 24 has an upper surface 48 and a lower surface 50, the lower surface 50 formed a plurality of connected points 52 and a plurality of through holes 54 penetrate upper surface 48 to lower surface 50, and the through holes 54 filled with metal 42, the upper surface 48 of the second substrate 24 is mounted on the bottom surface 46 of the heat sink 22, and the metal 42 which is filled within the through holes 54 contacted with heat sink 22.

In the embodiment comprise two upper memory chips 26 are mounted on the upper surface 32 of the first substrate 20 connected electrically to the connected points 52 of the first substrate 20 via golden ball 56 by filled-chip manner.

In the embodiment comprise two bottom memory chips 28 are mounted on the lower surface 50 of the second substrate 24 connected electrically to the connected points 52 of the second substrate 24 via golden ball by filled-chip manner.

Glue layer 26 coated the upper surface 32 of the first substrate 20 and the lower surface 50 of the second substrate 24 for encapsulating two up memory chips 20 and two bottom memory chips 28 at the same time.

Therefore, the small memory card of the present invention has the following advantages.

1. Since the heat of the upper memory chip 26 may be traveled to the heat sink 22 via the metal 42 which is filled within the through hole 40 of the first substrate 20, the heat can be rapidly spread out through heat sink 22, and the heat of the bottom memory chip 28 may be traveled to the heat sink via the metal 42 which is filled within the through hole 54 of the second substrate 24, the heat can be rapidly spread out through heat sink 22, so that, proving the durability and dependability of the small memory card.

2. Since the upper memory chip 26 is arranged on the upper surface 32 of the first substrate 20, and the bottom memory chip 28 is arranged on the lower surface 50 of the second substrate 24, then, the glue layer 30 coated every upper memory chips 26 and every bottom memory chips 28. So as to the manufacturing processes can be simplified, and the manufacturing costs also can be lowered.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A small memory card to be set in an electric device, comprising:
A first substrate having an upper surface and a lower surface, the upper surface formed with a plurality of connected points, a plurality of golden fingers electrically connected to the plurality of connected points, and a plurality of through holes penetrate the upper surface to the lower surface of the substrate, and the through holes being filled with metals, the first substrate is used to set in the electric device for electrically connecting the electric device to the golden finger;
A heat sink having a top surface and a bottom surface, the top surface being arranged under the lower surface of the first substrate, and being contacted with the metals, which is filled to the through holes;
A second substrate having an upper surface and a lower surface, the lower surface formed with a plurality of connected points and a plurality of through holes penetrate upper surface to lower surface of the substrate, and the through holes being filled with metals, the upper surface of the second substrate being arranged under the bottom surface of the heat sink, and the metal in the through holes contact with the heat sink;
At least one upper memory chip being mounted on the upper surface of the first substrate, and electrically connected to the connected points of the first substrate by filled-chip manner;
At least one bottom memory chip being mounted on the lower surface of the second substrate, and electrically connected to the connected points of the second substrate by coating manner;
A glue layer being coated the upper surface of the first substrate and the lower surface of the second substrate for encapsulating the each of the top memory chips and bottom memory chips.

2. The small memory card according to claim 1, wherein the metal filled with the each of through hole of the first substrate is copper.

3. The small memory card according to claim 1, wherein the metal filled with the each of through hole of the second substrate is copper.

4. The small memory card according to claim 1, wherein the heat sink is made of copper or aluminum.
